(19) United States
(12) Patent Application Publication
(10) Pub. No.: US 2022/0165546 A1
(43) Pub. Date: May 26, 2022

(54) PLASMA ETCH TOOL FOR HIGH ASPECT RATIO ETCHING

(71) Applicant: Lam Research Corporation, Fremont, CA (US)

(72) Inventors: Thorsten Lill, Santa Clara, CA (US); Ivan L. Berry, III, Green Valley, AZ (US); Theodoros Panagopoulos, Los Gatos, CA (US)

(21) Appl. No.: 17/593,117

(22) PCT Filed: Mar. 6, 2020
(86) PCT No.: PCT/US2020/021520

§ 371 Date: Sep. 9, 2021

Related U.S. Application Data
(60) Provisional application No. 62/818,552, filed on Mar. 14, 2019.

(51) Int. Cl. H01J 37/32

(52) U.S. Cl. CPC H01J 37/32422; H01J 37/32082; H01J 2237/3341; H01J 2237/0473; H01J 37/32706

(57) ABSTRACT

High aspect ratio features are etched using a plasma etching apparatus that can alternate between accelerating negative ions of reactive species at a low energy and accelerating positive ions of inert gas species at a high energy. The plasma etching apparatus can be divided into at least two regions that separate a plasma-generating space from an ionization space. Negative ions of the reactive species can be generated by electron attachment ionization in the ionization space when a plasma is ignited in the plasma-generating space. Positive ions of the inert gas species can be generated by Penning ionization in the ionization space when the plasma is quenched in the plasma-generating space.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Plasma etching processes are commonly used in the fabrication of semiconductor devices. More and more semiconductor devices are being scaled to increasingly narrower design rules. Feature sizes are decreasing and more and more features are being packed on a single wafer to create higher density structures. As device features shrink and the density of structures increases, the aspect ratio of an etched feature increases. Effectively etching high aspect ratio (HAR) features will be critical in meeting the design requirements of many semiconductor devices.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a plasma etching apparatus. The plasma etching apparatus includes a plasma generating source, an ionization space coupled to the plasma generating source and configured to generate ions, a first grid between the ionization space and the plasma generating source, an acceleration space coupled to the ionization space and configured to deliver the ions to a substrate in the acceleration space, a substrate support for supporting the substrate in the acceleration space, where the substrate support is configured to be biased, and a controller. The controller is configured with instructions for performing the following operations: accelerate negative ions of a reactive species to the substrate in the acceleration space by introducing the reactive species into the ionization space and applying a positive bias to the substrate support, and accelerate positive ions of a non-reactive species to the substrate in the acceleration space by introducing the non-reactive species into the ionization space and applying a negative bias to the substrate support.

In some implementations, the negative bias is substantially greater in absolute value than the positive bias. In some implementations, the positive bias is between about 0.5 V and about 10 V, and the negative bias is between about −50 kV and about −1 kV. In some implementations, the controller is further configured with instructions for performing the following operations: ignite plasma in the plasma generating source when accelerating the negative ions of the reactive species, and quench plasma in the plasma generating source when accelerating the positive ions of the non-reactive species. In some implementations, the controller is further configured with instructions for performing the following operation: in connection with accelerating the negative ions of the reactive species, extract electrons from the plasma to the ionization space to ionize the reactive species and form the negative ions of the reactive species in the ionization space. In some implementations, the controller is further configured with instructions for performing the following operation: in connection with accelerating the positive ions of the non-reactive species, cause diffusion of metastable species from the plasma to the ionization space to ionize the non-reactive species and form the positive ions of the non-reactive species in the ionization space. In some implementations, the plasma etching apparatus further includes a second grid between the ionization space and the acceleration space. A pressure in the ionization space may be greater than a pressure in the acceleration space.

Another aspect involves a plasma etching apparatus. The plasma etching apparatus includes a plasma generating source, an ionization space coupled to the plasma generating source and configured to generate ions, a first grid between the ionization space and the plasma generating source, an acceleration space coupled to the ionization space and configured to deliver the ions to a substrate in the acceleration space, a substrate support for supporting the substrate in the acceleration space, where the substrate support is configured to be biased, and a controller. The controller is configured with instructions for performing the following operations: introduce reactive species and non-reactive species to the ionization space, ignite plasma in the plasma generating source, apply a positive bias to the substrate support to ionize the reactive species and form negative ions of the reactive species and to accelerate negative ions of the reactive species to the substrate when the plasma is ignited, quench the plasma in the plasma generating source, and apply a negative bias to the substrate support to form positive ions of the non-reactive species and to accelerate positive ions of the non-reactive species to the substrate when the plasma is quenched.

In some implementations, the positive bias is between about 0.5 V and about 10 V, and wherein the negative bias is between about −50 kV and about −1 kV. In some implementations, a second grid between the ionization space and the acceleration space, where the first grid is configured to be biased and the second grid is configured to be biased, where a pressure in the ionization space is greater than a pressure in the acceleration space. In some implementations, the plasma generating source is an inductively coupled plasma (ICP) reactor or a capacitively coupled plasma (CCP) reactor. In some implementations, the controller is further configured with instructions for performing the following operation: repeat and alternate operations of applying the positive bias to the substrate support when the plasma is ignited and applying the negative bias to the substrate support when the plasma is quenched.

### BRIEF DESCRIPTION OF THE DRAWINGS

FIG. 1 is a schematic illustration of an example plasma etching apparatus that generates inductively-coupled plasma for etching.

FIG. 2 is a schematic illustration of an example plasma etching apparatus that generates capacitively-coupled plasma for etching.

FIGS. 3A-3C show schematic illustrations of an example reaction mechanism for etching silicon dioxide (SiO₂).

FIG. 4A is a schematic illustration of an example plasma etching apparatus divided by at least two grids, where the plasma etching apparatus generates inductively-coupled plasma and delivers alternating ion beams of positive and negative ions for etching according to some implementations.

FIG. 4B is a schematic illustration of an example plasma etching apparatus divided by a single grid, where the plasma etching apparatus generates inductively-coupled plasma and delivers alternating ion beams of positive and negative ions for etching according to some implementations.

FIG. 4C is a schematic illustration of an example plasma etching apparatus divided by at least two grids, where the plasma etching apparatus generates inductively-coupled plasma in a remote plasma source and delivers alternating ion beams of positive and negative ions for etching according to some implementations.

FIG. 4D is a schematic illustration of an example plasma etching apparatus divided by at least two grids, where the plasma etching apparatus generates capacitively-coupled plasma and delivers alternating ion beams of positive and negative ions for etching according to some implementations.

FIG. 5 shows a flow diagram of an example method of plasma etching using alternating ion beams of positive and negative ions according to some implementations.

FIGS. 6A and 6B show schematic illustrations of an example plasma etch process that alternates between a modification operation at FIG. 6A and a removal operation at FIG. 6B according to some implementations.

FIG. 7 illustrates an example timing sequence diagram for applied voltage to a plasma source and to a substrate support in a plasma etch process that alternates between a modification operation and a removal operation according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction

Plasma has long been employed for processing substrates. Plasma etching involves etching materials deposited on a substrate to form a desired pattern. Specifically, reactive ion etching (RIE) uses a chemically reactive plasma to remove materials deposited on substrates. Plasma is generated by supplying a plasma-generation chamber with reactant gases and applying an electromagnetic field. For example, plasma generation may employ capacitively-coupled plasma technology, inductively-coupled plasma technology, electron-cyclotron technology, or microwave technology. High-energy ions and radicals from the plasma are delivered to a substrate surface and react with materials deposited on the substrate.

In a plasma-generating chamber, reactant gases are introduced and plasma is generated by applying a strong radio-frequency (RF) electromagnetic field. Electrons are accelerated by the oscillating electric field, and the electrons collide with the reactant gas molecules to ionize the reactant gas molecules and strip them of their electrons, thereby creating a plasma of ions and more electrons. The plasma generally includes ions, radicals, neutral species, and electrons. In each cycle of the oscillating electric field, free electrons are electrically accelerated up and down in the plasma-generating chamber. Many of the free electrons may induce a negative bias at an electrode such as a substrate surface. Slower-moving ions are accelerated towards the biased electrode and react with materials on the substrate surface to be etched. The slower-moving ions may form a region that may be referred to as a sheath or plasma sheath. Typical sheath thickness is on the order of a few millimeters. Ion flux is generally normal to a surface of a substrate being processed.

Plasma reactors, such as inductively-coupled plasma reactors and capacitively-coupled plasma reactors, may generate plasmas with different characteristics. Generally speaking, inductively-coupled plasma reactors may be effective in performing conductor etch processes and capacitively-coupled plasma reactors may be effective in performing dielectric etch processes.

With inductively-coupled plasma reactors, high RF current in an external coil may generate an RF magnetic field in a plasma region which, in turn, generates an RF electric field in the plasma region. Inductively-coupled plasma reactors may utilize two RF generators to independently control plasma density and ion energy. With capacitively-coupled plasma reactors, energy is delivered to electrons in a plasma discharge by applying an RF voltage to an electrode. Multiple RF excitation frequencies can be used individually or simultaneously to alter plasma characteristics. Capacitively-coupled plasma reactors are typically able to achieve higher ion energies than inductively-coupled plasma reactors, and plasma density and ion energy are coupled rather than decoupled in inductively-coupled plasma reactors.

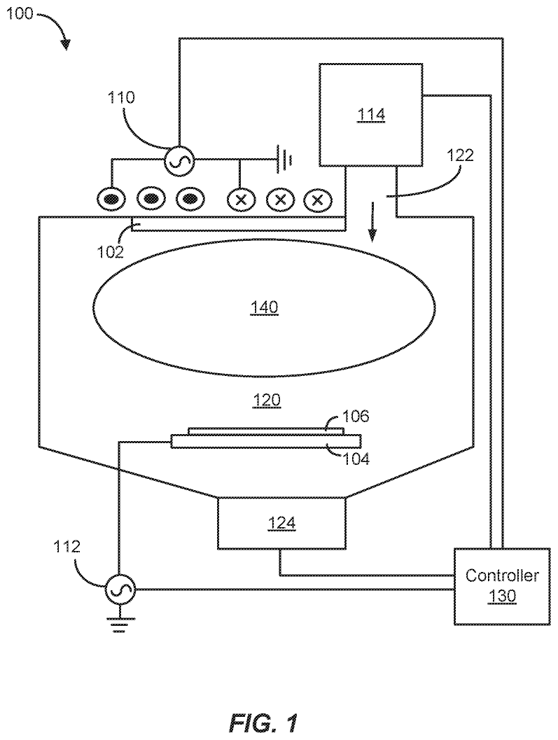

FIG. 1 is a schematic illustration of an example plasma etching apparatus that generates inductively-coupled plasma for etching. The plasma etching apparatus 100 includes an upper electrode 102 and a lower electrode 104 between which a plasma 140 may be generated. A substrate 106 may be positioned on the lower electrode 104 and may be held in place by an electrostatic chuck (ESC). Other clamping mechanisms may also be employed.

In the example in FIG. 1, the plasma etching apparatus 100 includes two RF sources, with RF source 110 connected to the upper electrode 102 and RF source 112 connected to the lower electrode 104. The plasma etching apparatus 100 may be an inductively-coupled plasma reactor. Though the plasma etching apparatus 100 is illustrated as an inductively-coupled plasma reactor, it will be appreciated that the plasma etching apparatus 100 may a capacitively-coupled plasma reactor with a single RF power source.

In FIG. 1, each of the RF sources 110 and 112 may include one or more sources of any appropriate frequency including 2 MHz, 13.56 MHz, 27 MHz, and 60 MHz. Reactant gas may be introduced to a processing chamber 120 from one or more gas sources 114. For example, the gas source 114 may include an inert gas such as argon (Ar), an oxygen-containing gas such as (O₂), a fluorine-containing gas such as CF₄, or any combination thereof. Reactant gas may be introduced to the processing chamber 120 through inlet 122 with excess gas and reaction byproducts exhausted via exhaust pump 124.

A controller 130 is connected to the RF sources 110 and 112 as well as to valves associated with the gas source 114. The controller 130 may further be connected to the exhaust pump 124. In some implementations, the controller 130 controls all of the activities of the plasma etching apparatus 100.

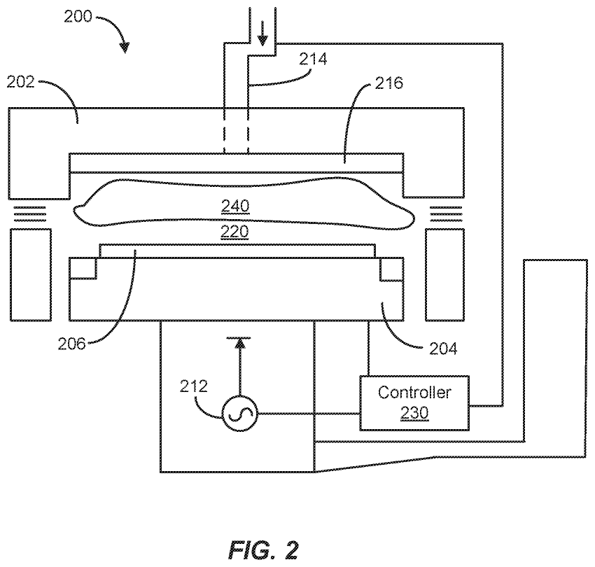

FIG. 2 is a schematic illustration of an example plasma etching apparatus that generates capacitively-coupled plasma for etching. The plasma etching apparatus 200 includes an upper electrode 202 and a lower electrode 204. The lower electrode 204 can include additional components such as a chuck or other clamping mechanism for holding a substrate 206. The lower electrode 204 may be supplied with RF power from an RF source 212. The RF source 212 may provide any appropriate frequency including 2 MHz, 13.56 MHz, 27 MHz, and 60 MHz. The RF source 212 may provide RF biasing to the lower electrode 204 during etching. The RF source 212 provides power to excite a process gas in a gap 220 between the upper electrode 202 and the lower electrode 204 to produce a plasma 240. The RF source 212 may be a single RF source that generates a high density plasma 240 in the gap 220. The process gas may be supplied to the gap 220 from a gas source 214. The process gas is supplied showerhead arrangement 216 and may flow through channels to enter the gap 220.

A controller 230 may be implemented with the plasma etching apparatus 200. The controller 230 may control some or all of the activities of the plasma etching apparatus 200. In some implementations, the controller may be connected to the lower electrode 204, RF source 212, and valves associated with the gas source 214.

Plasmas usually contain a mixture of ions and neutral species (e.g., radicals). Neutral species tend to lack directionality and provide a wide angular distribution. The neutral species tend to contribute to isotropic etching and sidewall etching. Ions, on the other hand, tend to have directionality in a direction that is substantially normal to a substrate surface and provide a narrow angular distribution. The ions tend to contribute to anisotropic etching. A mixture of ions and neutral species are used in aspect ratio dependent etching. Ratios, densities, and other characteristics of a plasma may be controlled in a plasma reactor, but aspect ratio dependent etching still proceeds with both ions and neutral species.

An ion beam etch reactor uses an ion beam to etch materials by sputtering. This type of etching is highly anisotropic and non-selective. A chemical etch reactor uses etchant gases to etch materials by chemical reactions at a substrate surface and forming volatile products. This type of etching is highly isotropic and selective. A plasma etch reactor generally uses ions and neutral species (e.g., radicals) to etch materials by ion bombardment and by chemical reactions on the substrate surface. This may be referred to as ion-enhanced etching. This type of etching may be moderately anisotropic and moderately selective. Etch directionality and etch profile may be influenced by controlling ion flux, ion energy, neutral/ion flux ratio, deposition or passivation chemistry, temperature of substrate surface, and pressure. However, with increasingly higher aspect ratio features, conventional plasma etching techniques and reactors may not sufficiently control etch directionality and etch profile in aspect ratio dependent etching.

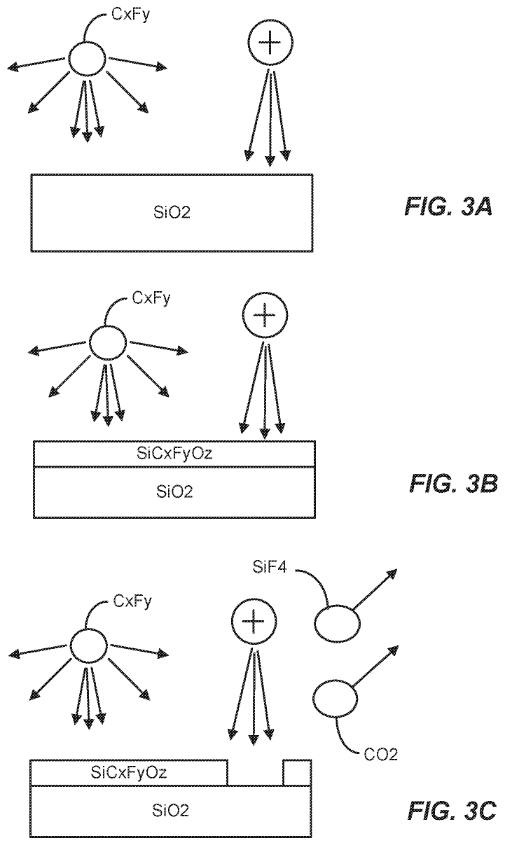

FIGS. 3A-3C show schematic illustrations of an example reaction mechanism for etching silicon dioxide (SiO₂). Many applications of aspect ratio dependent etching involve a combination of reactive species and non-reactive species. Plasma may be generated of reactive species and non-reactive species, where the plasma may include radicals of the reactive species and ions of the non-reactive species. A reactive species may include polymer precursors such as a fluorocarbon precursor (CₓF_{y}), where example fluorocarbon precursors may include CF₄ and C₄F₈. A non-reactive species may include one or more inert gases such as helium (He), argon (Ar), xenon (Xe), and krypton (Kr).

In FIG. 3A, radicals of CₓF_{y} may diffuse to the surface of the substrate having a layer of SiO₂ and ions of Ar⁺ may be accelerated to the surface of the substrate under biasing. The radicals and the ions may be intermixed. As shown in FIGS. 3A-3C, the radicals may lack directionality, where the horizontal components are similar in magnitude to the vertical components. The ions may have directionality in a direction that is substantially normal to the substrate surface, with the vertical components being greater than the horizontal components. The radicals move more slowly to the substrate surface than the ions.

The radicals under ion bombardment may form a chemically reactive layer of SiC_{X}F_{y}O_{z} in FIG. 3B. The radicals may tend to saturate on the substrate surface and react chemically with the substrate surface. Moreover, the radicals may tend to condense and form films on the substrate surface. Without being limited by any theory, ion beam mixing with radicals of CₓF_{y} may play an important contribution in the formation of the chemically reactive layer.

In FIG. 3C, the energetic ions of Ar⁺ may collide with and penetrate the substrate surface. This causes the chemically reactive layer of SiC_{X}F_{y}O_{Z} to be desorbed as etch byproducts such as SiF₄ and CO₂. These etch byproducts may be removed from the chemically reactive layer of SiC_{X}F_{y}O_{Z}, thereby etching some of the SiO₂.

In a conventional plasma etch reactor, such as a plasma etching apparatus in FIG. 1 or a plasma etching apparatus in FIG. 2, plasma is generated containing a mixture of ions and neutral species. Etching high aspect ratio features may occur by supplying increasing amounts of RF power during plasma generation, thereby generating higher ion energies by electron collisions. A thick sheath of ions is generated, and the ions may be accelerated through the thick sheath by RF biasing. However, this way of generating higher ion energies and accelerating ions is inefficient and costly, and still results in a wide ion energy distribution function (IEDF) and a wide ion angular distribution function (IADF). Accordingly, a conventional plasma etch reactor may be limited in its effectiveness for high aspect ratio etching applications.

A conventional plasma etch reactor may be substituted with an ion beam etch reactor so that ions are completely separated out for etching, but reactive species (e.g., neutral species) from the plasma are often necessary also for etching high aspect ratio features. Thus, using an ion beam etch reactor may be impractical for many high aspect ratio etching applications.

As mentioned above, controlling parameters such as ion/neutral flux ratio may influence etch directionality and etch profile. The ion/neutral flux ratio may be adjusted with aspect ratio in aspect ratio dependent etching. Higher ion/neutral flux ratio may provide more anisotropic etching and lower ion/neutral flux ratio may provide more selective etching. The ion/neutral flux ratio may change during etching. For example, in a conventional plasma etch reactor, the ion/neutral flux ratio may be adjusted by mixed mode pulsing (MMP). Each pulse of a gas cycle may have varying amounts of reactive species (e.g., neutral species) to non-reactive species (e.g., inert gas). Plasma power and/or frequency may be different during each pulse of the gas cycle. In other words, RF settings and flow settings may be alternatingly changed with each pulse to change ion/neutral flux ratio. With mixed mode pulsing, ratios of ions to neutral species may be changed temporally. However, mixed mode pulsing may be relatively slow due to constant gas switching between reactive species and non-reactive species. Furthermore, though mixed mode pulsing can provide different RF powers/frequencies for each pulse, different RF powers/frequencies do not fundamentally alter chemistries. With electron impact ionization occurring in a conventional plasma etch reactor, neutral species and ions are not completely separated out during etching even with mixed mode pulsing.

A conventional plasma etch reactor that relies on both ions and neutral species for aspect ratio dependent etching is also presented with a challenge that neutral species diffuse very slowly towards the bottom of a feature. Etching high aspect ratio features may involve flowing neutral species to adsorb onto an exposed surface and form a reactive layer, and accelerating ions towards the surface to remove the reactive layer. Plasma generated in a conventional plasma etch reactor typically has a wide IEDF and wide IADF. Neutral species have energies at around a few eV and ions have energies at around tens or hundreds of eV. Neutral species lack directionality and it is difficult to etch high aspect ratio features (e.g., deep trenches) with wide IEDF and wide IADF. While the ions having high ion energies may be accelerated with bias pulsing, the neutral species having low ion energies diffuse very slowly in all directions. The neutral species may not necessarily reach the bottom of a feature but may collide on sidewalls of the feature. This results in a low etch rate.

In etching high aspect ratio features, accelerating ions in a conventional plasma etch reactors may result in charges building up on masks. The buildup of charge on the masks may repel ions from reaching the bottom of a feature. This diminishes the etching at the bottom of the feature and increases etching at the sidewalls, which results in “bowing.” A conventional plasma etch reactor may increase ion energies to overcome charge repulsion and reach the bottom of the high aspect ratio features, but this increases cost.

In addition, a conventional plasma etch reactor may form various etch byproducts in removing materials from a substrate. Typically, the etch byproducts are pumped out of the plasma etch reactor by one or more pumping mechanisms. However, the etch byproducts may not be entirely removed. When a plasma is ignited, such etch byproducts may be ionized and re-deposited on the substrate. A waferless automated clean (WAC) may be performed in between operations to remove etch byproducts, but this increases cost.

### Plasma Etching Apparatus

The plasma etching apparatus of the present disclosure may address the foregoing challenges of high aspect ratio etching. The plasma etching apparatus can be divided into two or more volumes that separate a plasma-generation space and an ionization space. In some implementations, the plasma etching apparatus can be divided into at least three volumes that separate a plasma-generation space, an ionization space, and an acceleration space. In some implementations, a grid separates at least the plasma-generation space and the ionization space, where the grid may be biased or grounded. An electrode or substrate support for supporting a substrate may be biased by a DC voltage to create an electric field with the grid. During a first phase of an etch process, electrons generated in a plasma-generation space may react with reactive species to form negative ions in the ionization space by electron attachment ionization, where the negative ions are accelerated to a substrate surface to modify materials at the substrate surface. During a second phase of the etch process, plasma is quenched and residual metastable neutral species may react with inert gas species to form positive ions in the ionization space by Penning ionization, where the positive ions are accelerated to the substrate surface to etch the modified materials at the substrate surface. The first and second phases of the etch process may be alternated and repeated to complete the etch process. As used herein, the negative ions may also be referred to as “fast neutrals,” “accelerated neutrals,” “non-dissociated reactive ions,” or “reactive ions.” The positive ions may also be referred to as “non-reactive ions” or “inert gas ions.” The plasma etching apparatus may perform high aspect ratio etching by fully separating fast neutrals and non-reactive ions.

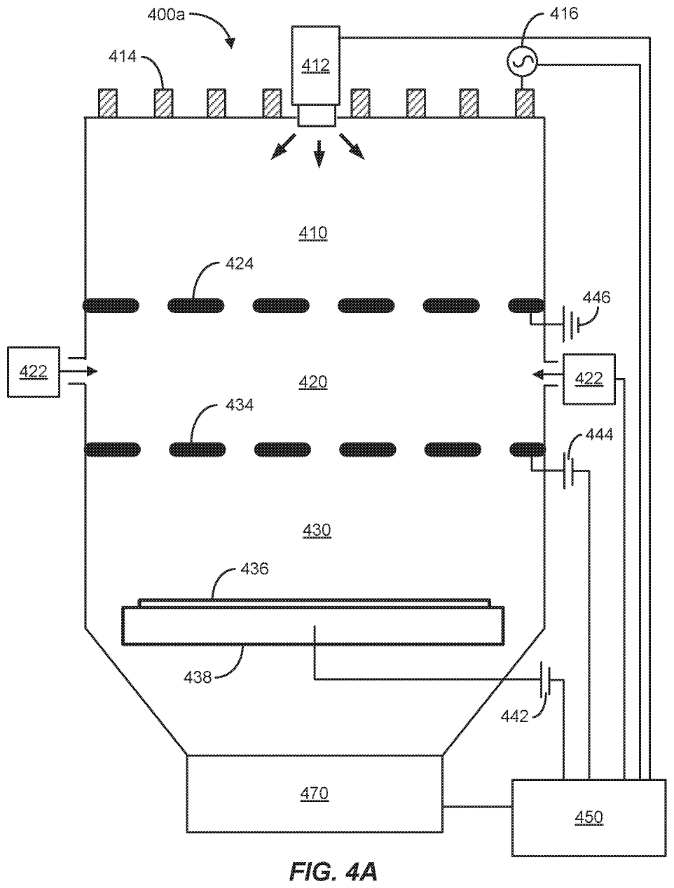

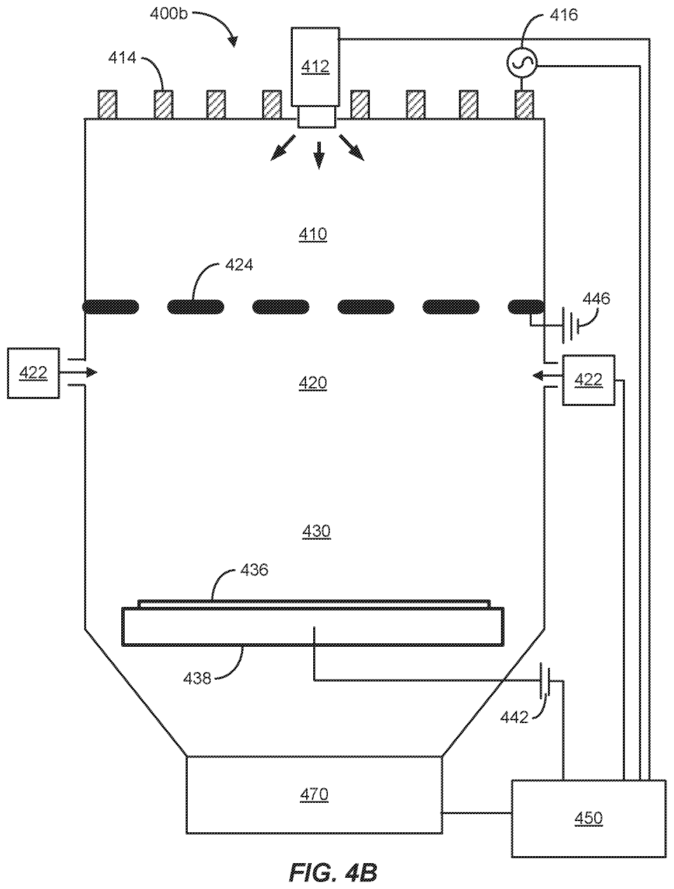

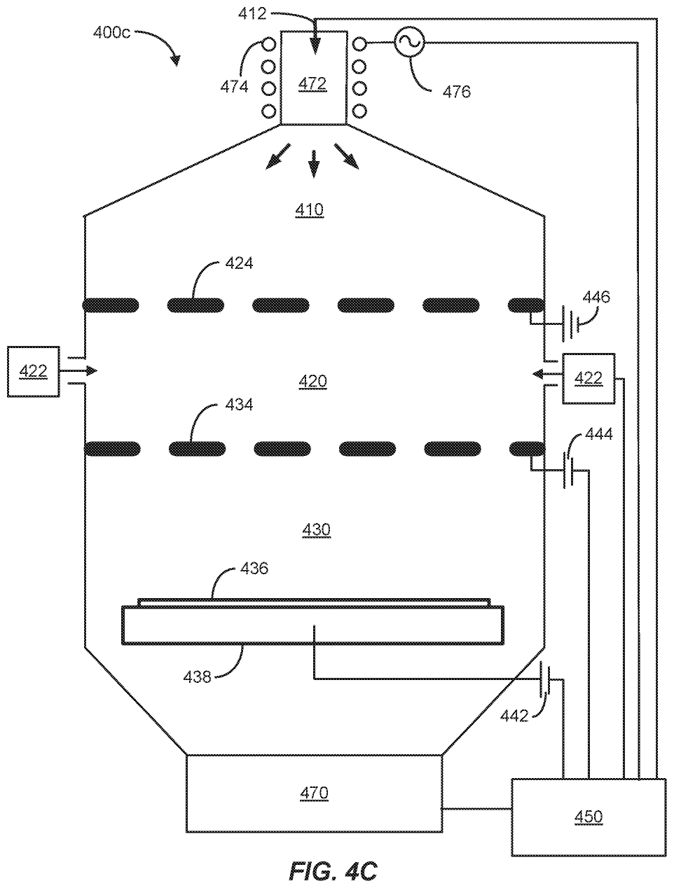

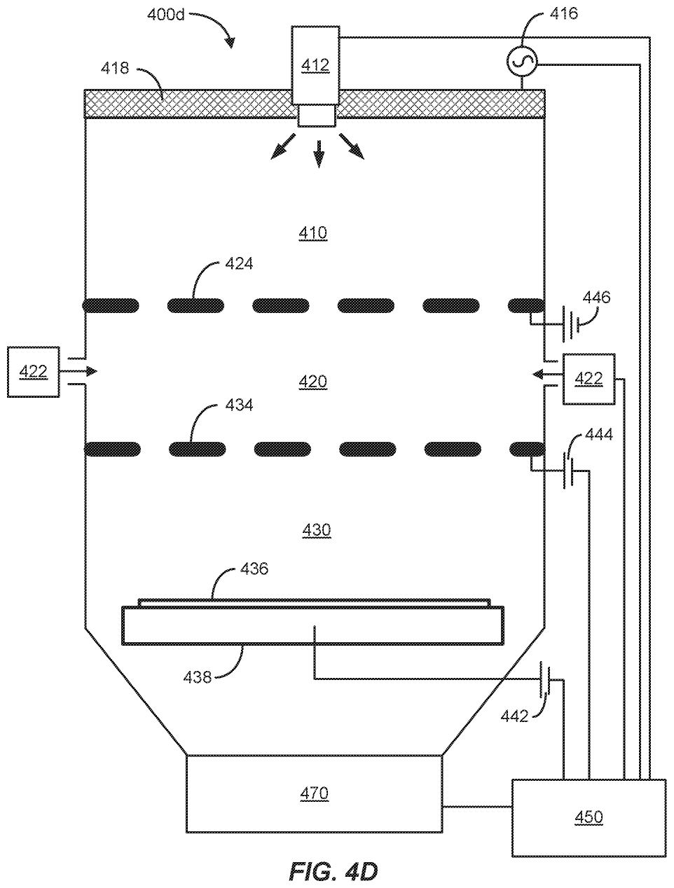

FIG. 4A is a schematic illustration of an example plasma etching apparatus divided by at least two grids, where the plasma etching apparatus generates inductively-coupled plasma and delivers alternating ion beams of positive and negative ions for etching according to some implementations. The plasma etching apparatus 400a includes a plasma generating source 410 for generating plasma, an ionization space 420 coupled to the plasma generating source 410 and configured to generate ions, and an acceleration space 430 coupled to the ionization space 420 and configured to deliver ions to a substrate 436 positioned in the acceleration space 430. The plasma etching apparatus 400a may include a first grid 424 between the plasma generating source 410 and the ionization space 420. In some implementations, the plasma etching apparatus 400a may further include a second grid 434 between the ionization space 420 and the acceleration space 430. The plasma generating source 410 may be upstream from the ionization space 420, and the ionization space 420 may be upstream from the acceleration space 430.

A first gas or first gas mixture may be introduced into the plasma generating source 410 from a first gas source 412. The first gas source 412 may be in fluid communication with the plasma generating source 410. One or more valves, mass flow controllers (MFCs), and/or mixing manifolds may be associated with the first gas source 412 to control flow of the first gas into the plasma generating source 410. The first gas may include a noble gas such as helium, argon, xenon, or krypton. In some implementations, the first gas may be delivered continuously during an etch process. In some implementations, the first gas may be pulsed in separate phases of the etch process.

RF power may be supplied to the plasma generating source 410 to generate plasma of the first gas in the plasma generating source 410. In some implementations, the plasma generating source 410 may include an RF antenna 414 coupled to an RF generator 416. In some implementations, the RF generator 416 may include an RF power supply coupled to a matching network. In some implementations, the RF antenna 414 may include a planar spiral coil. In some implementations as shown in FIG. 4A, the plasma generating source 410 of the plasma etching apparatus 400a is an inductively-coupled plasma (ICP) reactor. However, it will be appreciated that the present disclosure may employ a capacitively-coupled plasma (CCP) reactor or other type of plasma reactor for generating plasma. In use, the first gas is delivered to the plasma generating source 410 and RF power is supplied from the RF generator 416 to the RF antenna 414 to generate plasma in the plasma generating source 410. With electron impact ionization, electrons collide with the first gas and strip them of their electrons to produce ions as well as more electrons. During a first phase of the etch process, RF power may be supplied to generate plasma of the first gas in the plasma generating source 410. During a second phase of the etch process, RF power may be turned off to quench plasma in the plasma generating source 410.

As discussed in more detail below, an etch process may constitute an etch cycle broken up into two phases. The first phase may constitute a modification phase where plasma is turned on and the second phase may constitute a removal phase where plasma is turned off.

The plasma generating source 410 is coupled to the ionization space 420 via the first grid 424. Ions, electrons, or neutral species may be extracted from the plasma generated in the plasma generating source 410 through the first grid 424. In some implementations, the first grid 424 may include a plurality of openings or apertures through which the ions, electrons, or neutrals may pass through. In some implementations, the first grid 424 may include a conductive plate having the plurality of openings or apertures, where the conductive plate may be biased or grounded. In some implementations as shown in FIG. 4A, the first grid 424 may be grounded by an electrical ground 446. However, it will be understood that in some implementations the first grid 424 may be biased. The first grid 424 may form an electric field with the second grid 434 or with the substrate support 438. Depending on the potential gradient of the electric field, certain charged species and/or neutral species may be extracted through the first grid 424 from the plasma. Electrons may be extracted during a first phase of the etch process for electron attachment ionization, and metastable neutral species may be extracted during a second phase of the etch process for Penning ionization. The first phase may constitute the modification phase where electrons are extracted from a plasma through the first grid 424, and the second phase may constitute the removal phase where metastable neutral species are extracted from a plasma afterglow through the first grid 424.

Electron attachment ionization and Penning ionization may occur in the ionization space 420. A second gas or second gas mixture may be introduced into the ionization space 420 from one or more additional gas sources 422. The second gas may include a reactive gas or reactive species. Examples of reactive species include halogen gases such as chlorine (Cl₂), bromine (Br₂), fluorine (F₂), or iodine (I₂), perfluorocarbons such as tetrafluoromethane (CF₄), octafluorocyclobutane (C₄F₈), and hexafluorocyclobutene (C₄F₆), hydrofluorocarbons such as trifluoromethane (CHF₃), difluoromethane (CH₂F₂), and fluoromethane (CH₃F), and oxygen (02). Generally, the second gas is an electronegative reactive gas. A third gas or third gas mixture may be introduced into the ionization space 420 from the one or more additional gas sources 422. The third gas may include a non-reactive species such as helium, argon, xenon, or krypton. In some implementations, the third gas is different than the first gas. In some implementations, the second gas and the third gas may be delivered into the ionization space 420 through different gas inlets fluidly coupled to the one or more additional gas sources 422. One or more valves, mass flow controllers (MFCs), and/or mixing manifolds may be associated with the one or more additional gas sources 422 to control flow of the second gas and the third gas into the ionization space 420. In some implementations, the second gas and the third gas may be continuously supplied into the ionization space 420 during the first phase and the second phase of the etch process. In some other implementations, the second gas and the third gas may be supplied in pulses into the ionization space 420 so that the second gas is provided in the first phase and the third gas is provided during the second phase.

Electrons extracted through the first grid 424 may cause electron attachment ionization of the second gas. This forms negative ions of the reactive species. Negative ions of the reactive species are formed without dissociation by electron attachment ionization. Electron attachment ionization may occur during the first phase of the etch process. Thus, electron attachment ionization to form negative ions of the reactive species occurs during the modification phase of the etch process. An example formula for electron attachment ionization with C₄F₈ is shown below:

e⁻+C₄F₈⁻->C₄F₈⁻

Metastable neutral species extracted through the first grid 424 may cause Penning ionization of the third gas. This forms positive ions of the non-reactive species. The metastable neutral species may be extracted through the first grid 424 even after the plasma in the plasma generating source 410 is quenched or turned off. In some implementations, the metastable neutral species may be in an excited state. The metastable neutral species may have a sufficiently long lifetime to diffuse through the first grid 424 and collide with the non-reactive species. The collision may cause Penning ionization of the non-reactive species so that the non-reactive species is stripped of an electron. Penning ionization may occur during the second phase of the etch process. Hence, Penning ionization to form positive ions of the non-reactive species occurs during the removal phase of the etch process. An example formula for Penning ionization with Ar and metastable He⁺ is shown below:

He⁺+Ar-->Ar⁺+He+e⁻

A substrate 436 may be supported on a substrate support 438 in the acceleration space 430. The substrate 436 may include a plurality of high aspect ratio features in some implementations. High aspect ratio features may include features having a depth to width aspect ratio of at least 10:1, at least 20:1, at least 50:1, or at least 100:1. The substrate support 438 is configured to be biased by a DC voltage. The substrate support 438 may include a chuck or other clamping mechanism for holding the substrate 436. The substrate support 438 may include an electrode that is electrically connected to a DC power supply 442 for applying a negative or positive DC voltage to the substrate support 438. The biased substrate support 438 may cause ions to be accelerated towards the substrate 436. Negative ions or fast neutrals may be accelerated towards the substrate 436 by application of a positive bias during the first phase (modification phase) of the etch process, and positive ions or non-reactive ions may be accelerated towards the substrate 436 by application of a negative bias during the second phase (removal phase) of the etch process.

The positive bias may create a weak electric field between the substrate support 438 and the second grid 434 or the first grid 424 so that the negative ions are accelerated at low energies. The negative bias may create a strong electric field between the substrate support 438 and the second grid 434 or the first grid 424 so that the positive ions are accelerated at high energies. In some implementations, the negative bias may be substantially greater in absolute value than the positive bias. In some implementations, the positive bias may be between about 0.5 V and about 10 V, and the negative bias may be between about −50 kV and about −1 kV. The accelerated negative ions during the modification phase of the etch process serve to modify or activate a substrate surface and can form a reactive layer on the substrate surface. The accelerated positive ions during the removal phase of the etch process serve to etch the reactive layer on the substrate surface.

In some implementations as shown in FIG. 4A, the ionization space 420 is coupled to the acceleration space 430 via the second grid 434. The first grid 424 may divide the plasma generating source 410 from the ionization space 420, and the second grid 434 may divide the ionization space 420 from the acceleration space 430. Utilization of both the first grid 424 and the second grid 434 may enhance ionization. With the first grid 424 and the second grid 434, the ionization space 420 may operate at a different pressure than the acceleration space 430. In some implementations, a pressure in the ionization space 420 is greater than a pressure in the acceleration space 430. Higher pressures in the ionization space 420 promote more collisions and more ionization. In some implementations, the pressure in the ionization space 420 is between about 10 mTorr and about 1000 mTorr, such as about 500 mTorr. Reduced pressures in the acceleration space 430 promote acceleration with fewer collisions. In some implementations, the pressure in the acceleration space 430 is between about 1 mTorr and about 50 mTorr, such as about 4 mTorr.

Aspects of the second grid 434 may be similar to the first grid 424. In some implementations, the second grid 434 may include a plurality of openings or apertures through which the ions, electrons, or neutrals may pass through. In some implementations, the second grid 434 may include a conductive plate having the plurality of openings or apertures, where the conductive plate may be biased or grounded. In some implementations as shown in FIG. 4A, the second grid 434 includes an electrode that is electrically connected to a DC power supply 444 for applying a negative or positive DC voltage to the second grid 434. For example, during the first phase of the etch process, the second grid 434 may be positively biased to draw electrons from the plasma generating source 410 and into the ionization space 420. During the second phase of the etch process, the second grid 434 may be negatively biased to accelerate positive ions out of the ionization space 420. Though the implementation in FIG. 4A is illustrated with the first grid 424 and the second grid 434, it will be understood that the plasma etching apparatus 400a may include any number of grids such as three, four, five, or more grids.

The plasma etching apparatus 400a may further include an exhaust pump 470. The exhaust pump 470 may include a roughing pump and/or turbomolecular pump in fluid communication with the acceleration space 430. The exhaust pump 470 is used to control pressure in the plasma etching apparatus 400a such as the pressure in the acceleration space 430. The exhaust pump 470 is further used to evacuate various gases from the acceleration space 430.

The modification phase and the removal phase of the etch process may be alternatingly repeated in the plasma etching apparatus 400a. In the modification phase, plasma is generated in the plasma generating source 410, electrons are extracted from the plasma through the first grid 424, electron attachment ionization occurs in the ionization space 420 to form negative ions of reactive species, the negative ions are accelerated by a positive bias applied to a substrate support 438 in the acceleration space 430, and a substrate surface is modified by the negative ions. In the removal phase, plasma is turned off in the plasma generating source 410, metastable neutral species are extracted from a plasma afterglow through the first grid 424, Penning ionization occurs in the ionization space 420 to form positive ions of the non-reactive species, the positive ions are accelerated by a negative bias applied to the substrate support 438 in the acceleration space 430, and a modified layer on the substrate surface is removed by the positive ions.

The plasma etching apparatus 400a may further include a controller 450. The controller 450 (which may include one or more physical or logical controllers) controls some or all of the operations of the plasma etching apparatus 400a. The controller 450 may be configured with instructions for performing the modification phase and removal phase of the etch process. That way, the controller 450 may selectively ionize the reactive species and the non-reactive species in alternating phases, and the controller 450 may accelerate ion beams of negative ions and positive ions in alternating phases. In some implementations, the controller 450 may be used to control the RF generator 416 connected to the RF antenna 414, the first gas source 412 for delivering the first gas, the one or more additional gas sources 422 for delivering the second gas and the third gas, the DC power supply 444 electrically connected to the second grid 434, the DC power supply 442 electrically connected to the substrate support 438, the exhaust pump 470, or combinations thereof. In some implementations, the controller 450 may be configured with instructions for applying RF power to the plasma generating source 410 during the modification phase and turning off RF power to the plasma generating source 410 during the removal phase. In some implementations, the controller 450 may be configured with instructions for applying a positive bias to the substrate support 438 during the modification phase for extracting electrons from the plasma generating source 410 and for accelerating negative ions of reactive species to the substrate 436, and applying a negative bias to the substrate support 438 during the removal phase for accelerating positive ions of non-reactive species to the substrate 436. Application of the positive bias may extract electrons from a plasma to ionize reactive species and form negative ions of the reactive species. Application of the negative bias may cause diffusion of metastable species from a plasma or its afterglow to ionize non-reactive species and form positive ions of the non-reactive species.

The controller 450 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller 450 they may be provided over a network. In certain implementations, the controller 450 executes system control software. The system control software may include instructions for controlling the timing of application and/or magnitude of any one or more of the following chamber operational conditions: the mixture and/or composition of gases, flow rates of gases, chamber pressure, chamber temperature, substrate/substrate support temperature, substrate position, substrate support tilt, substrate support rotation, voltage applied to a grid, voltage applied to a substrate support, the frequency and power applied to coils, antenna, or other plasma generation components, and other parameters of a particular process performed by the tool. The system control software may further control purge operations and cleaning operations through the exhaust pump 470. System control software may be configured in any suitable way. For example, various process tool component subroutines or control objects may be written to control operations of the process tool components necessary to carry out various process tool processes. System control software may be coded in any suitable compute readable programming language.

In some implementations, system control software includes input/output control (IOC) sequencing instructions for controlling the various parameters described above. For example, each phase of a semiconductor fabrication process may include one or more instructions for execution by the controller 450. The instructions for setting process conditions for a phase may be included in a corresponding recipe phase, for example. In some implementations, the recipe phases may be sequentially arranged, such that steps in a plasma etching process are executed in a certain order for that process phase. For example, a recipe may be configured to perform plasma generation and acceleration of negative ions during a first phase, and acceleration of positive ions with plasma power turned off during a second phase.

Other computer software and/or programs may be employed in some implementations. Examples of programs or sections of programs for this purpose include substrate positioning program, a process gas composition control program, a pressure control program, a heater control program, and an RF power supply control program.

The controller 450 may control these and other aspects based on sensor output (e.g., when power, potential, pressure, gas levels, etc. reach a certain threshold), the timing of an operation (e.g., applying power at certain times of a process), or based on received instructions from the user.

Broadly speaking, the controller 450 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 450 in the form of various individual settings (or program files), defining operational parameters for carrying out a particular process on or for a semiconductor substrate or to a system. The operational parameters may, in some implementations, be part of a recipe defined by process engineers to accomplish one or more processing steps during plasma etching.

The controller 450, in some implementations, may be a part of or coupled to a computer that is integrated with, coupled to the system, otherwise networked to the system, or a combination thereof. For example, the controller 450 may be in the “cloud” or all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 450 receives instructions in the form of data, which specify parameters for each of the processing steps to be performed during one or more operations. It should be understood that the parameters may be specific to the type of process to be performed and the type of tool that the controller 450 is configured to interface with or control. Thus as described above, the controller 450 may be distributed, such as by comprising one or more discrete controllers that are networked together and working towards a common purpose, such as the processes and controls described herein. An example of a distributed controller 450 for such purposes would be one or more integrated circuits on a chamber in communication with one or more integrated circuits located remotely (such as at the platform level or as part of a remote computer) that combine to control a process on the chamber.

As noted above, depending on the process step or steps to be performed by the tool, the controller 450 might communicate with one or more of other tool circuits or modules, other tool components, cluster tools, other tool interfaces, adjacent tools, neighboring tools, tools located throughout a factory, a main computer, another controller, or tools used in material transport that bring containers of substrates to and from tool locations and/or load ports in a semiconductor manufacturing factory.

In some implementations, the controller 450 is configured with instructions for performing the following operations: accelerate negative ions of a reactive species to the substrate 436 in the acceleration space 430 by introducing the reactive species into the ionization space 420 and applying a positive bias to the substrate support 430, and accelerate positive ions of a non-reactive species to the substrate 436 in the acceleration space 430 by introducing the non-reactive species into the ionization space 420 and applying a negative bias to the substrate support 438. The controller 450 may be further configured with instructions for performing the following operations: ignite plasma in the plasma generating source 410 when accelerating the negative ions of the reactive species, and quench plasma in the plasma generating source 410 when accelerating the positive ions of the non-reactive species. The controller 450 may be further configured with instructions for performing the following operation: in connection with accelerating the negative ions of the reactive species, extract electrons from the plasma to the ionization space 420 to ionize the reactive species and form the negative ions of the reactive species in the ionization space 420. This may occur by application of the positive bias to the substrate support 438. The controller 450 may be further configured with instructions for performing the following operation: in connection with accelerating the positive ions of the non-reactive species, cause diffusion of metastable species from the plasma to the ionization space 420 to ionize the non-reactive species and form the positive ions of the non-reactive species in the ionization space 420. This may occur by application of the negative bias to the substrate support 438. The controller 450 may be further configured with instructions for performing the following operations: in connection with accelerating the negative ions of the reactive species, form a reactive layer on a material layer of the substrate 436, and in connection with accelerating the positive ions of the non-reactive species, etch the material layer of the substrate 436, where the material layer includes a dielectric material or electrically conductive material. The controller 450 may be further configured with instructions for performing the following operations: repeat and alternate operations of accelerating the negative ions of the reactive species and accelerating the positive ions of the non-reactive species.

FIG. 4B is a schematic illustration of an example plasma etching apparatus divided by a single grid, where the plasma etching apparatus generates inductively-coupled plasma and delivers alternating ion beams of positive and negative ions for etching according to some implementations. Aspects of a plasma etching apparatus 400b in FIG. 4B may be similar to the plasma etching apparatus 400a in FIG. 4A except no second grid is present in the plasma etching apparatus 400b. Accordingly, the ionization space 420 and the acceleration space 430 occupy an integrated volume and are not divided by any physical structure. The pressure in the ionization space 420 and the acceleration space 430 may be the same. Ions are effectively generated and accelerated in the same integrated volume of the plasma etching apparatus 400b.

FIG. 4C is a schematic illustration of an example plasma etching apparatus divided by at least two grids, where the plasma etching apparatus generates inductively-coupled plasma in a remote plasma source and delivers alternating ion beams of positive and negative ions for etching according to some implementations. Aspects of a plasma etching apparatus 400c in FIG. 4C may be similar to the plasma etching apparatus 400a in FIG. 4A except that the plasma generating source 410 is coupled to a remote inductive source 472 in the plasma etching apparatus 400c. RF current from an RF generator 476 may be applied to coils 474 to generate an RF electric field in the remote inductive source 472 and forms a downstream plasma in the plasma generating source 410. Inductively-coupled remote plasma reactors may generate higher density plasmas than capacitively-coupled plasma reactors. Accordingly, the inductively-coupled remote plasma reactor may be used to increase electron density and metastable species density. This may also be true of capacitively-coupled remote plasma reactors compared to capacitively-coupled plasma reactors. In some implementations, the plasma etching apparatus 400c may include a single grid instead of two or more grids.

FIG. 4D is a schematic illustration of an example plasma etching apparatus divided by at least two grids, where the plasma etching apparatus generates capacitively-coupled plasma and delivers alternating ion beams of positive and negative ions for etching according to some implementations. Aspects of a plasma etching apparatus 400d in FIG. 4D may be similar to the plasma etching apparatus 400a of FIG. 4A except that the plasma generating source 410 is a capacitively-coupled plasma reactor in the plasma etching apparatus 400d. RF power may be supplied from the RF generator 416 to an electrode 418 to generate plasma in the plasma generating source 410. The first grid 424 may be biased or grounded, and plasma may be formed between the electrode 418 and the first grid 424 in the capacitively-coupled plasma reactor. In some implementations, the plasma etching apparatus 400d may include a single grid instead of two or more grids. In addition, it will be appreciated that the plasma etching apparatuses 400a-400d in FIGS. 4A-4D may utilize any number of grids and may utilize any suitable plasma generating technology such as CCP technology, ICP technology, electron-cyclotron technology, or microwave technology.

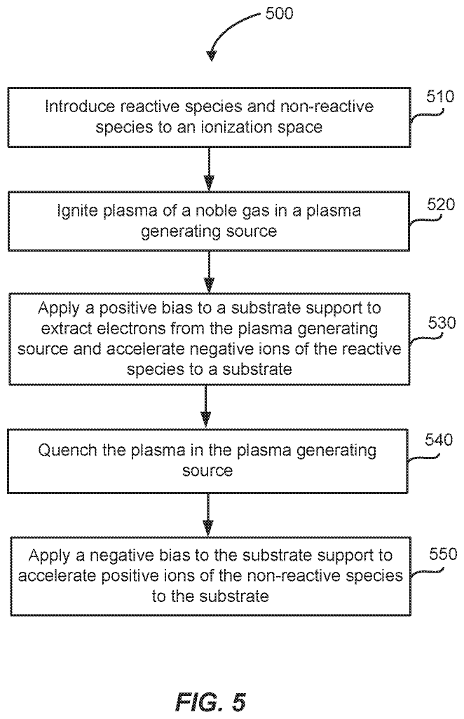

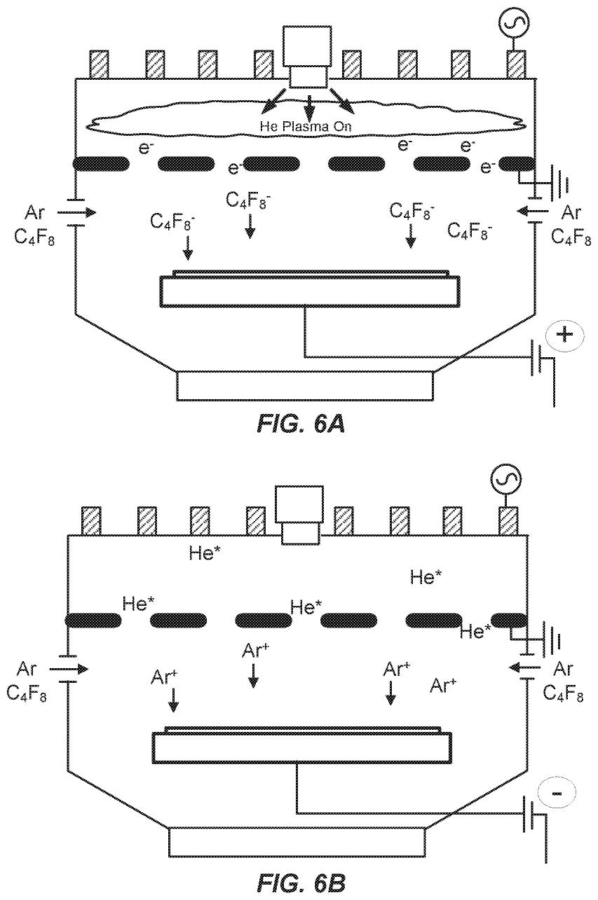

FIG. 5 shows a flow diagram of an example method of plasma etching using alternating ion beams of positive and negative ions according to some implementations. Operations of a process 500 in FIG. 5 may include additional, fewer, or different operations. Accompanying the description of the process 500 in FIG. 5 is a series of cross-sectional schematic illustrations showing a modification operation in FIG. 6A and a removal operation in FIG. 6B. FIGS. 6A and 6B show schematic illustrations of an example plasma etch process that alternates between a modification operation at FIG. 6A and a removal operation at FIG. 6B according to some implementations. Operations of the process 500 may be performed using a plasma etching apparatus such as one of the plasma etching apparatuses 400a-400d in FIGS. 4A-4D.

At block 510 of the process 500, reactive species and non-reactive species are introduced to an ionization space. The reactive species and non-reactive species may flow directly into the ionization space of a plasma etching apparatus in the gas phase. The ionization space may be a separate volume from a plasma generating source, where a first grid may divide the ionization space and the plasma generating source. The ionization space may be downstream from the plasma generating source. The first grid may include a conductive plate having a plurality of openings or apertures through which ions, electrons, and neutral species of a noble gas may pass through. The reactive species may include an electronegative reactive gas species such as a halogen, perfluorocarbon, hydrofluorocarbon, or oxygen. For example, the reactive species includes C₄F₈. The non-reactive species may include an inert gas such as helium, argon, xenon, or krypton. The non-reactive species may be different than a noble gas provided to the plasma generating source. In some implementations, the reactive species and the non-reactive species may be introduced continuously throughout the process 500 or for a specified period of time during the process 500. In some implementations, the reactive species and the non-reactive species may be introduced in separate pulses during the process 500. For example, one or both of the reactive species and non-reactive species may be introduced during a first phase of the process 500, or one or both of the reactive species and non-reactive species may be introduced during a second phase of the process 500.

A first phase constitutes a modification phase and may include at least blocks 520 and 530 of the process 500. In some implementations, the first phase further includes block 510. A second phase constitutes a removal phase and may include at least blocks 540 and 550 of the process 500. In some implementations, the second phase further includes block 510.

At block 520 of the process 500, plasma of a noble gas is ignited in the plasma generating source. In some implementations, the noble gas is introduced into the plasma generating source prior to block 520 or during block 520. The noble gas may include helium, argon, xenon, or krypton. For example, the noble gas includes helium. Plasma of the noble gas may include a mixture of ions, electrons, and neutral species of the noble gas. In some implementations, the plasma generating source may be a CCP reactor or ICP reactor. During plasma ignition at block 520, plasma is turned on.

At block 530 of the process 500, a positive bias is applied to a substrate support to extract electrons from the plasma generating source and accelerate negative ions of the reactive species to a substrate. The substrate may be supported on the substrate support in an acceleration space, where the acceleration space may represent a volume in the plasma etching apparatus that is integrated with the ionization space or separate from the ionization space. The acceleration space may be downstream from the ionization space. The substrate may include a material layer to be etched, where the material layer can include a dielectric material or electrically conductive material. In some implementations, the substrate may include a plurality of high aspect ratio features having a depth to width aspect ratio of at least 10:1, at least 20:1, at least 50:1, or at least 100:1.

Electrons may be extracted from the plasma in the plasma generating source through the first grid. In some implementations, the first grid may be electrically grounded and the substrate support outside the plasma generating source is positively biased to extract electrons through the first grid. In some implementations, the first grid may be negatively biased and the substrate support outside the plasma generating source is positively biased to extract electrons through the first grid. The electrons are extracted from the plasma as a result of an electric field established between the positively biased substrate support and the grounded or negatively biased grid. The electrons are extracted while the plasma is turned on. Without being limited by any theory, the extracted electrons may collide with the reactive species and form negative ions of the reactive species by electron attachment ionization. The ions of the reactive species are not dissociated. Electrons are extracted at energies that cause electron attachment ionization with the reactive species but not with the non-reactive species. For example, the electrons may be extracted at energies between about 1 eV and about 5 eV for electron attachment of C₄F₈ to form C₄F₈⁻. In some implementations, the positive bias applied to the substrate support is between about 0.5 V and about 10 V, or between about 1 V and about 5 V.

As negative ions of the reactive species are formed by electron attachment ionization, the positive bias applied to the substrate support causes acceleration of the negative ions to the substrate. The negative ions of the reactive species are accelerated to the substrate in a manner to limit or prevent sputtering at a substrate surface. Specifically, the positive bias applied to the substrate support may be maintained between about 0.5 V and about 10 V, or between about 1 V and about 5 V. By applying a small positive bias, the accelerated negative ions can modify or activate the substrate surface rather than sputter atoms/molecules from the substrate surface. In some implementations, the accelerated negative ions are adsorbed on the substrate surface to form a reactive layer for etching. The material layer on the substrate may be converted to the reactive layer, where the reactive layer may be etched during the removal phase of the process 500.

Operations at blocks 520 and 530 in the modification phase may be performed simultaneously or sequentially. The operation at block 510 may be performed prior to or during the operations at blocks 520 and 530.

FIG. 6A shows a schematic illustration of an example plasma etching apparatus undergoing a modification phase of an etch process. Such a modification phase may include operations at blocks 510, 520, and 530 of the process 500 in FIG. 5. Helium gas is delivered into a plasma generating source such as a CCP reactor. Though the plasma generating source is shown as a CCP reactor, it will be understood that the plasma generating source may be any suitable plasma reactor. Helium plasma is generated by the plasma generating source. A positive DC voltage is applied to a substrate support on which a substrate is supported. The positive bias causes electrons to be extracted through a grid between the plasma generating source and an ionization space. Reactive gas such as C₄F₈ and non-reactive gas such as Ar are introduced into the ionization space. Extracted electrons cause ionization without dissociation of the reactive gas to form negative ions of the reactive gas. As shown in FIG. 6A, C₄F₈ is ionized by electron attachment ionization to form C₄F₈⁻. The negative ions of the reactive gas are accelerated by the positive bias to the substrate to activate or modify a substrate surface of the substrate. For example, the C₄F₈⁻ may form a reactive layer on the substrate surface. Though a single grid is shown in the plasma etching apparatus, it will be understood that a second grid may be provided in the plasma etching apparatus to divide the ionization space between an ionization space in which ionization occurs and an acceleration space in which the substrate is located. Therefore, the modification phase of the etch process may involve turning a plasma on to ignite plasma, applying a positive bias to a substrate support, extracting electrons from the plasma, ionizing reactive species to form negative ions of the reactive species, and accelerating the negative ions to a substrate to modify a substrate surface.

Returning to FIG. 5, at block 540 of the process 500, plasma is quenched in the plasma generating source. No RF power is applied to the plasma generating source to ignite or sustain the plasma. In other words, plasma is turned off. Without plasma discharge, charged species of the noble gas are not generated. However, metastable species such as metastable neutral species of the noble gas may linger in the plasma generating source even after plasma is turned off. Metastable species of the noble gas may have a sufficiently long lifetime to diffuse through the first grid and into the ionization space. In particular, the metastable species of the noble gas may diffuse into the ionization space during an afterglow.

The metastable species that diffuse into the ionization space after plasma is turned off may collide with the non-reactive species and form positive ions of the non-reactive species. The metastable species may be in an excited state. Without being limited by any theory, the metastable species in the excited state may cause Penning ionization with the non-reactive species but not the reactive species. For example, metastable helium radicals (He⁺) in an excited state may have a lifetime of a few seconds and an energy of several eV. This lifetime is long enough for collisions to occur before decaying and the metastable helium radicals possess sufficient energy in the excited state to ionize an inert gas species such as Ar. The metastable helium radicals may ionize Ar to form Ar⁺.

At block 550 of the process 500, a negative bias is applied to the substrate support to accelerate positive ions of the non-reactive species to the substrate. As positive ions of the inert gas species are formed by Penning ionization, the negative bias applied to the substrate support causes acceleration of the positive ions to the substrate. The positive ions of the non-reactive species are accelerated to the substrate in a manner to promote ion bombardment and chemically enhanced sputtering at the substrate surface. The positive ions may strike and penetrate the substrate surface with energies between about 1000 eV and about 50000 eV. In some implementations, the negative bias applied to the substrate support may be between about −50 kV and about −1 kV, or between about −10 kV and about −1 kV. By applying a large negative bias, the accelerated positive ions can etch materials formed on the substrate surface. In some implementations, the accelerated positive ions intermix with the reactive layer to cause the reactive layer to be etched.

Operations at blocks 540 and 550 in the removal phase may be performed simultaneously or sequentially. The operation at block 510 may be performed prior to or during the operations at blocks 540 and 550.

FIG. 6B shows a schematic illustration of an example plasma etching apparatus undergoing a removal phase of the etch process. Such a removal phase may include operations at blocks 510, 540, and 550 of the process 500 in FIG. 5. Power is not applied to the plasma generating source so that plasma in the plasma generating source is quenched. The helium plasma is turned off, leaving only metastable helium radicals in the plasma afterglow. The metastable helium radicals may be in an excited state and may diffuse through the grid. Reactive gas such as C₄F₈ and non-reactive gas such as Ar are introduced into the ionization space. The extracted metastable helium radicals cause ionization of the non-reactive gas to form positive ions of the non-reactive gas. As shown in FIG. 6B, Ar is ionized by Penning ionization to form Ar⁺. A negative DC voltage is applied to the substrate support on which the substrate is supported. The negative bias causes the positive ions of the non-reactive gas to be accelerated to the substrate to remove the reactive layer on the substrate surface by chemically enhanced sputtering. For example, Ar⁺ may remove the reactive layer formed by adsorbed C₄F₈⁻ on the substrate surface. Thus, the removal phase of the etch process may involve turning a plasma off to quench the plasma, applying a negative bias to a substrate support, extracting metastable neutral species, ionizing non-reactive species to form positive ions of the non-reactive species, and accelerating the positive ions to a substrate to etch materials from a substrate surface.

Returning to FIG. 5, the process 500 may further include repeating the modification phase at blocks 520 and 530 and the removal phase at blocks 540 and 550 in an alternating manner. The modification phase and the removal phase may continuously alternate to complete the process 500 for plasma etching. In some implementations, the modification phase and the removal phase may continuously alternate to complete the process 500 for plasma etching high aspect ratio features on the substrate. The process 500 may alternate between electron attachment ionization in the modification phase and Penning ionization in the removal phase. In addition, the process 500 may alternate between accelerating fast neutrals at low energy in the modification phase and accelerating positive ions at high energy in the removal phase. Moreover, the process 500 may alternate between plasma on in the modification phase and plasma off in the removal phase.

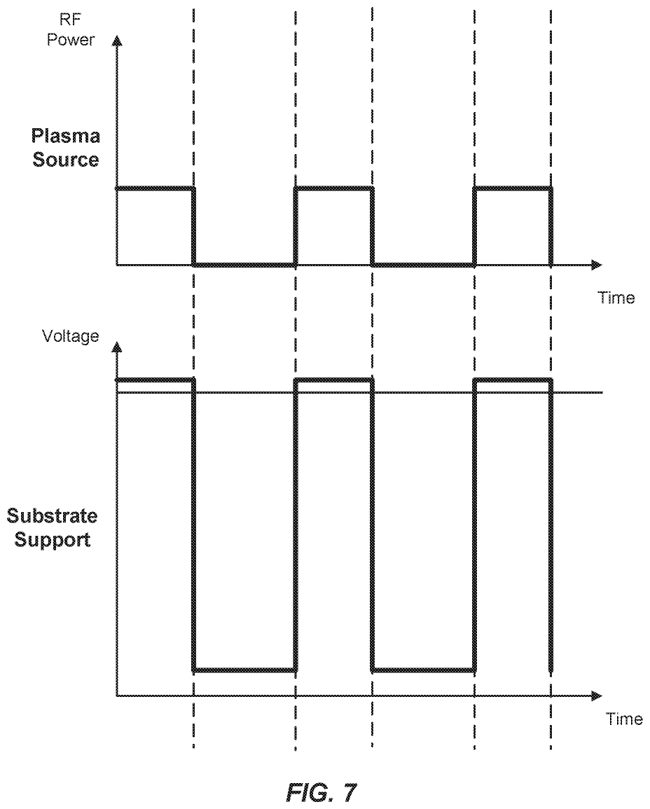

FIG. 7 illustrates an example timing sequence diagram for applied power to a plasma source and applied voltage to a substrate support in a plasma etch process that alternates between a modification operation and a removal operation according to some implementations. The modification operation and the removal operation may constitute an etch cycle. In some implementations, the etch cycle may last between about 1 ms and about 50 ms. A duration of the modification operation may be between about 1 ms and about 10 ms, and a duration of the removal operation may be between about 1 ms and about 10 ms. The modification operation and its duration may occur in connection with accelerating negative ions of reactive species or in connection with application of a positive bias to a substrate support. The removal operation and its duration may occur in connection with accelerating positive ions of non-reactive species or in connection with application of a negative bias to a substrate support.

As shown in FIG. 7, power is applied to the plasma source during the modification operation and the substrate support is marginally biased with a positive DC voltage. The positive DC voltage may be between about 1 V and about 5 V. As shown in FIG. 7, no power is applied to the plasma source during the removal operation and the substrate support is substantially biased with a negative DC voltage. The negative DC voltage may be between about −50 kV and −1 kV. A controller may be configured to provide instructions for applied power to the plasma source and applied voltage to the substrate support in alternating between the modification operation and the removal operation.

The plasma etching apparatus of the present disclosure provides alternating ion beams of negative ions of reactive species and positive ions of non-reactive species for plasma etching. Fast neutrals may modify a substrate surface by DC acceleration at low energy, and positive ions may etch materials from the substrate surface by DC acceleration at high energy. The fast neutrals are provided with a narrow IEDF and narrow IADF. Rather than acceleration of a sheath by RF bias in conventional plasma etch reactors that results in wide IEDF and wide IADF, acceleration of negative ions and positive ions occur separately by DC acceleration. Instead of mixed mode pulsing in conventional plasma etch reactors for balancing ion/neutral flux ratio, the present disclosure may separate ion flux and neutral flux by separating positive ions at high energies and negative ions at low energies. Whereas the conventional plasma etch reactor ionizes by electron impact ionization, the present disclosure may achieve selective ionization by selecting between electron attachment ionization to form negative ions and Penning ionization to form positive ions. Fast neutrals having low energies and having a narrow IADF may be generated by electron attachment ionization, thereby avoiding neutral species diffusing very slowly to a bottom of a high aspect ratio feature. Furthermore, charge buildup on masks is avoided by alternating ion beams of positive and negative ions. Re-deposition of etch byproducts is also avoided by separating a plasma generating region from an etching region with one or more grids, which prevents backstreaming of etch byproducts into the plasma generating region. Moreover, dielectric etch and conductor etch may be performed by the plasma etching apparatus of the present disclosure regardless of whether the plasma reactor is a CCP reactor or ICP reactor.

### CONCLUSION

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A plasma etching apparatus comprising:
a plasma generating source;
an ionization space coupled to the plasma generating source and configured to generate ions;
a first grid between the ionization space and the plasma generating source;
an acceleration space coupled to the ionization space and configured to deliver the ions to a substrate in the acceleration space;
a substrate support for supporting the substrate in the acceleration space, wherein the substrate support is configured to be biased; and
a controller configured with instructions for performing the following operations:
accelerate negative ions of a reactive species to the substrate in the acceleration space by introducing the reactive species into the ionization space and applying a positive bias to the substrate support; and
accelerate positive ions of a non-reactive species to the substrate in the acceleration space by introducing the non-reactive species into the ionization space and applying a negative bias to the substrate support.

2. The plasma etching apparatus of claim 1, wherein the negative bias is substantially greater in absolute value than the positive bias.

3. The plasma etching apparatus of claim 2, wherein the positive bias is between about 0.5 V and about 10 V, and wherein the negative bias is between about −50 kV and about −1 kV.

4. The plasma etching apparatus of claim 1, wherein the controller is further configured with instructions for performing the following operations:
in connection with accelerating the negative ions of the reactive species, form a reactive layer on a material layer of the substrate, and
in connection with accelerating the positive ions of the non-reactive species, etch the material layer of the substrate, wherein the material layer includes a dielectric material or electrically conductive material.

5. The plasma etching apparatus of claim 1, wherein the controller is further configured with instructions to perform the following operations:
ignite plasma in the plasma generating source when accelerating the negative ions of the reactive species; and
quench plasma in the plasma generating source when accelerating the positive ions of the non-reactive species.

6. The plasma etching apparatus of claim 5, wherein the controller is further configured with instructions for performing the following operations:
in connection with accelerating the negative ions of the reactive species, extract electrons from the plasma to the ionization space to ionize the reactive species and form the negative ions of the reactive species in the ionization space.

7. The plasma etching apparatus of claim 5, wherein the controller is further configured with instructions for performing the following operations:
in connection with accelerating the positive ions of the non-reactive species, cause diffusion of metastable species from the plasma to the ionization space to ionize the non-reactive species and form the positive ions of the non-reactive species in the ionization space.

8. The plasma etching apparatus of claim 1, wherein the first grid is configured to be biased or grounded, and wherein the controller is further configured with instructions for performing the following operations:
in connection with accelerating the negative ions, form a weak electric field between the first grid and the substrate support, and
in connection with accelerating the positive ions, form a strong electric field between the first grid and the substrate support.

9. The plasma etching apparatus of claim 1, wherein the substrate includes a plurality of high aspect ratio features having a depth to width aspect ratio of at least 10:1.

10. The plasma etching apparatus of claim 1, further comprising:
a second grid between the ionization space and the acceleration space.

11. The plasma etching apparatus of claim 10, wherein a pressure in the ionization space is greater than a pressure in the acceleration space.

12. The plasma etching apparatus of claim 10, wherein the second grid is configured to be biased.

13. The plasma etching apparatus of claim 1, wherein the plasma generating source is a inductively coupled plasma (ICP) reactor or a capacitively coupled plasma (CCP) reactor.

14. The plasma etching apparatus of claim 1, wherein the controller is further configured with instructions for performing the following operations:
repeat and alternate operations of accelerating the negative ions of the reactive species and accelerating the positive ions of the non-reactive species.

15. The plasma etching apparatus of claim 1, wherein the controller is further configured with instructions for performing the following operations:
in connection with accelerating the negative ions of the reactive species, accelerate the negative ions of the reactive species for a first duration between about 1 ms and about 10 ms, and
in connection with accelerating the positive ions of the non-reactive species, accelerate the positive ions of the non-reactive species for a second duration between about 1 ms and about 10 ms.

16. A plasma etching apparatus comprising:
a plasma generating source;
an ionization space coupled to the plasma generating source and configured to generate ions;
a first grid between the ionization space and the plasma generating source;
an acceleration space coupled to the ionization space and configured to deliver the ions to a substrate in the acceleration space;
a substrate support for supporting the substrate in the acceleration space, wherein the substrate support is configured to be biased; and
a controller configured with instructions for performing the following operations:
introduce reactive species and non-reactive species to the ionization space;
ignite plasma in the plasma generating source;
apply a positive bias to the substrate support to ionize the reactive species and form negative ions of the reactive species, and to accelerate the negative ions of the reactive species to the substrate when the plasma is ignited;
quench the plasma in the plasma generating source; and
apply a negative bias to the substrate support to ionize the non-reactive species and form positive ions of the non-reactive species, and to accelerate the positive ions of the non-reactive species to the substrate when the plasma is quenched.

17. The plasma etching apparatus of claim 16, wherein the positive bias is between about 0.5 V and about 10 V, and wherein the negative bias is between about −50 kV and about −1 kV.

18. The plasma etching apparatus of claim 16, further comprising:
a second grid between the ionization space and the acceleration space, wherein the first grid is configured to be biased and the second grid is configured to be biased, wherein a pressure in the ionization space is greater than a pressure in the acceleration space.

19. The plasma etching apparatus of claim 16, wherein the plasma generating source is an inductively coupled plasma (ICP) reactor or a capacitively coupled plasma (CCP) reactor.

20. The plasma etching apparatus of claim 16, wherein the controller is further configured with instructions for performing the following operation:
repeat and alternate operations of applying the positive bias to the substrate support when the plasma is ignited and applying the negative bias to the substrate support when the plasma is quenched.
